(19) United States
(12) Patent Application Publication
(10) Pub. No.: US 2026/0005663 A1
(43) Pub. Date: Jan. 1, 2026

(54) POWER AMPLIFIER

(71) Applicant: Bonsai Systems Inc., Vancouver (CA)

(72) Inventors: Jurgen HISSEN, Port Moody (CA); Bernard Joseph Andre GUAY, Vancouver (CA); Matthew William MCADAM, Vancouver (CA)

(21) Appl. No.: 18/759,031

(22) Filed: Jun. 28, 2024

(51) Int. Cl. H03F 3/60; H03F 1/02; H03F 3/24

(52) U.S. Cl. CPC H03F 3/605; H03F 1/0288; H03F 3/24; H03F 2200/451

(57) ABSTRACT

A radio frequency power amplifier for processing an RF input signal is provided. A splitter may distribute an RF input signal into a plurality of sub-path input signals distributed over a plurality of paths. A plurality of sub-path control units may receive the sub-path input signals and provide one or more of phase control, gain control and bias control to produce a plurality of sub-path output signals distributed over a plurality of configurable sub-paths, each path comprising at least one configurable path and at least one sub-path signal having a piecewise linear response. A combiner network may combine the sub-path output signals to generate an RF output signal. The plurality of configurable sub-paths may be configured such that the RF output concurrently achieves a linearity target and a power efficiency target across a full amplitude range of the RF output signal.

### FIELD

The present disclosure relates to electronic devices, including but not limited to a power amplifier and associated systems, computing platforms, methods, and storage media. BACKGROUND

Wireless communication systems are continuously evolving. Power amplifiers (PAs) are used in a number of different applications, including in wireless communication systems. A power amplifier may need to divide an input signal to different paths, in order to split the input power.

Environmental and manufacturing variations may result in non-ideal performance characteristics for the power amplifier. Some known approaches enable phase and gain control of an input signal before the input signal is provided to the power amplifier. However, such known approaches are not able to sufficiently account for changes in environment and for manufacturing variances, resulting in undesirable performance characteristics for the power amplifier.

Improvements in approaches relating to power amplifiers are desirable.

### BRIEF DESCRIPTION OF THE DRAWINGS

Embodiments of the present disclosure will now be described, by way of example only, with reference to the attached Figures.

FIG. 1 is a block diagram illustrating a power amplifier, in accordance with one or more embodiments.

FIG. 2 illustrates a sub-path control unit for a sub-path of the power amplifier of FIG. 1, in accordance with one or more embodiments.

FIG. 3 illustrates a graph showing path output voltage versus path input voltage for a piecewise linear combination within a path in a power amplifier, in accordance with one or more embodiments.

FIG. 4 is a block diagram illustrating a power amplifier with N paths, in accordance with one or more embodiments.

FIG. 5 is a functional block diagram illustrating an apparatus, in accordance with one or more embodiments, such as a power amplifier.

FIG. 6 illustrates a method for processing a signal in a power amplifier, in accordance with one or more embodiments.

### DETAILED DESCRIPTION

A radio frequency power amplifier, apparatus and method for processing an RF input signal are provided.

A radio frequency power amplifier, apparatus and method for processing an RF input signal are provided. A splitter may distribute an RF input signal into a plurality of sub-path input signals distributed over a plurality of paths. A plurality of sub-path control units may receive the plurality of sub-path input signals and provide one or more of phase control, gain control and bias control to produce a plurality of sub-path output signals distributed over a plurality of configurable sub-paths, each path comprising at least one configurable path and at least one sub-path signal having a piecewise linear response. A combiner network may combine the plurality of sub-path output signals to generate an RF output signal. The plurality of configurable sub-paths may be configured such that the RF output concurrently achieves a linearity target and a power efficiency target across a full amplitude range of the RF output signal.

Embodiments of the present disclosure provide a load-modulated intelligent RF power amplifier comprising at least two and up to N driver paths, with at least one path, each path comprising up to M sub-paths. A set of up to M sub-paths may comprise a main sub-path, and zero or more secondary (or “kink”) sub-paths. A separate sub-path control unit may be provided for each configurable sub-path, providing one or more of fine phase control, gain control and bias control of the sub-paths, for optimization of one or more of gain, output power, linearity and efficiency.

Among known approaches with respect to PA implementation is a Doherty amplifier. A Doherty amplifier is a simple load-modulated PA with 2 driver paths and 2 sub-paths, with only 1 sub-path per path. To achieve a linear output, each path and sub-path in a Doherty amplifier must be linear. An embodiment of the present disclosure may comprise two paths, each with at least one sub-path, where at least one of the sub-paths comprises has a piecewise linear response. Embodiments of the present disclosure may comprise N paths and M sub-paths per path, going far beyond the Doherty amplifier to achieve superior performance.

In an embodiment, the present disclosure provides a radio frequency power amplifier comprising: a splitter configured to perform a distribution of an RF input signal into a plurality of sub-path input signals distributed over a plurality of paths; a plurality of sub-path control units configured to receive the plurality of sub-path input signals and to provide one or more of phase control, gain control and bias control to produce a plurality of sub-path output signals distributed over a plurality of configurable sub-paths, each of the plurality of paths comprising at least one configurable sub-path, at least one of the sub-path output signals having a piecewise linear response; a plurality of sub-path combiners configured to combine the plurality of sub-path output signals into a plurality of path signals; and a path combiner configured to combine the plurality of path signals and to generate an RF output signal, the plurality of configurable sub-paths being configured, and the plurality of sub-path control units cooperating, such that the RF output concurrently achieves a linearity target and a power efficiency target across a full amplitude range of the RF output signal.

In an embodiment, the present disclosure provides a processor-implemented method for processing a radio frequency (RF) input signal, the method comprising: receiving the RF input signal; performing a distribution of the RF input signal into a plurality of sub-path signals, the plurality of sub-path signals distributed over a plurality of paths; performing one or more of phase control, gain control and bias control with respect to the plurality of sub-path signals to produce a plurality of sub-path output signals distributed over a plurality of configurable sub-paths, at least one of the sub-path output signals having a piecewise linear response; and combining the plurality of sub-path output signals to generate an RF output signal, the plurality of configurable sub-paths configured such that the RF output concurrently achieves a linearity target and a power efficiency target across a full amplitude range of the RF output signal.

In an embodiment, the present disclosure provides an apparatus comprising: a non-transient computer-readable storage medium having executable instructions embodied thereon; and one or more hardware processors configured to execute the instructions to: receive the RF input signal; perform a distribution of the RF input signal into a plurality of sub-path signals, the plurality of sub-path signals distributed over a plurality of paths; perform one or more of phase control, gain control and bias control with respect to the plurality of sub-path signals to produce a plurality of sub-path output signals distributed over a plurality of configurable sub-paths, at least one of the sub-path output signals having a piecewise linear response; and combine the plurality of sub-path output signals to generate an RF output signal, the plurality of configurable sub-paths configured such that the RF output concurrently achieves a linearity target and a power efficiency target across a full amplitude range of the RF output signal.

For the purpose of promoting an understanding of the principles of the disclosure, reference will now be made to the features illustrated in the drawings and specific language will be used to describe the same. It will nevertheless be understood that no limitation of the scope of the disclosure is thereby intended. Any alterations and further modifications, and any further applications of the principles of the disclosure as described herein are contemplated as would normally occur to one skilled in the art to which the disclosure relates. It will be apparent to those skilled in the relevant art that some features that are not relevant to the present disclosure may not be shown in the drawings for the sake of clarity.

Certain terms used in this application and their meaning as used in this context are set forth in the description below. To the extent a term used herein is not defined, it should be given the broadest definition persons in the pertinent art have given that term as reflected in at least one printed publication or issued patent. Further, the present processes are not limited by the usage of the terms shown below, as all equivalents, synonyms, new developments and terms or processes that serve the same or a similar purpose are considered to be within the scope of the present disclosure.

Embodiments of the present disclosure comprise a PA that employs a plurality of paths and a plurality of configurable sub-paths to generate an RF output signal that concurrently achieves a linearity target and a power efficiency target across a full amplitude range of the RF output signal. An RF power amplifier of embodiments of the present disclosure combines behaviours of the different configurable sub-paths to achieve a desired behaviour for the RF output signal, where at least one of the sub-path output signals has a piecewise linear response. In an embodiment, the sub-paths and paths may combine to achieve the desired behaviour for the RF power amplifier as a whole. Within a path, one sub-path may include non-ideal behaviour, and another sub-path may be used to achieve a linearity target across the full amplitude range of the RF output signal. In another embodiment, a configurable sub-path may be used to produce a particular behaviour and/or correct for non-idealities in the configurable sub-path itself, or in other sub-paths or paths.

Embodiments of the present disclosure are designed to operate in scenarios in which at least one sub-path in the PA has a non-linear response, such as a piecewise linear response. A piecewise linear response is a combination of straight lines that is not linear as a whole; each section or piece may be linear, but the overall curve is not linear. When at least one-sub path in the PA has a non-linear response, then at least one path has a non-linear response. The sub-path control units of embodiments of the present disclosure are configured to compensate for non-linearity in one or more of the sub-paths to achieve the linearity target for the RF output signal.

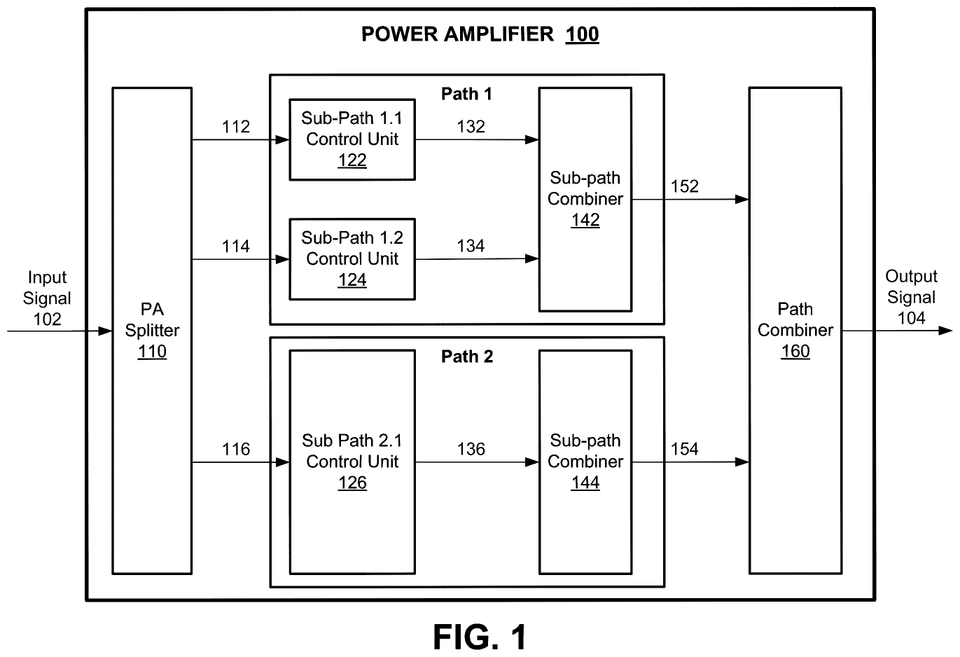

FIG. 1 is a block diagram illustrating a load balanced radio frequency power amplifier 100, in accordance with one or more embodiments. The RF PA 100 may receive and control an RF input signal 102, and may distribute or split the input signal 102 over a plurality of paths.

The RF power amplifier 100 of FIG. 1 comprises a splitter 110 configured to perform a distribution, for example a linear separation, of the input signal 102 into a plurality of sub-path signals 112, 114 and 116 distributed over a plurality of paths. In an example embodiment described in relation to FIG. 1, the plurality of sub-path signals includes first and second sub-path signals 112 and 114 associated with a first path and a third sub-path signal 116 associated with a second path. First sub-path signal 112 may be described as relating to sub-path 1.1, and second sub-path signal 114 may be described as relating to sub-path 1.2, where sub-paths 1.1 and 1.2 are sub-paths of path 1. Similarly, third sub-path signal 116 may be described as relating to sub-path 2.1, which is a sub-path of path 2.

The PA 100 comprises a plurality of sub-path control units 122, 124 . . . 126 configured to receive the plurality of sub-path signals and to provide one or more of phase control, gain control and bias control of the to produce a plurality of sub-path output signals distributed over a plurality of configurable sub-paths. For example, a configurable sub-path is a sub-path on which a sub-path control unit is provided. In an example embodiment, each of the plurality of paths comprises at least one configurable sub-path. At least one of the sub-path output signals has a piecewise linear response. In a particular embodiment, at least one of the plurality of paths comprises at least two configurable sub-paths. This is in contrast to some known approaches according to which each path can only have one sub-path.

The PA 100 may comprise a plurality of paths, and each path may have a plurality of sub-paths. In an example embodiment, each sub-path may comprise a sub-path control unit. In another example embodiment, a set of sub-path control units is provided on a subset of the sub-paths, and the set of sub-path control units may be configured to compensate for the piecewise linear response of one of more sub-path output signals. The piecewise linear response may be on a sub-path that has a sub-path control unit. Alternatively, the sub-path control unit(s) may compensate for a piecewise linear response on at least one sub-path having a piecewise linear response, even if the piecewise linear response is on a different sub-path than the sub-path control unit(s).

In an example embodiment, the PA 100 comprises a plurality of paths, such as the two paths 1 and 2 shown in FIG. 1. Each path acts on one or more of the sub-path input signals and each path produces a path output signal.

For example, as part of path 1, sub-path 1.1 control unit 122 is associated with sub-path 1.1 and configured to receive sub-path input signal 112 and to provide one or more of phase control, gain control and bias control to produce sub-path output signal 132. Also as part of path 1, sub-path 1.2 control unit 124 is associated with sub-path 1.2 and configured to receive sub-path input signal 114 and to provide one or more of phase control, gain control and bias control to produce sub-path output signal 134. As part of path 2, sub-path 2.1 control unit 126 is associated with sub-path 2.1 and configured to receive sub-path input signal 116 and to provide one or more of phase control, gain control and bias control to produce sub-path output signal 136.

The PA 100 may comprise a combiner network configured to combine the plurality of sub-path output signals to generate an RF output signal. In the example embodiment of FIG. 1, a path combiner 160 combines signals provided from first and second sub-path combiners 142 and 144. A first sub-path combiner 142 is configured to combine sub-path output signals 132 and 134 to generate a path 1 output signal 152. A second path combiner 144 is configured to combine sub-path output signals for path 2, which in this case include only 136, to generate a path 2 output signal 154. The path combiner 160 is configured to combine the path output signals 152 and 154 to generate an RF output signal 104.

The plurality of configurable sub-paths may be configured, and the associated plurality of sub-path control units 122, 124 . . . 126 cooperate, such that the RF output concurrently achieves a linearity target and a power efficiency target across a full amplitude range of the RF output signal. The linearity target may comprise a target with respect to an amount of linearity for the RF output signal 104. The linearity target for the RF output may be substantially linear, within a given tolerance according to a specification for the PA. The power efficiency target may comprise a target with respect to a power efficiency value or rating for the RF output signal 104. Embodiments of the present disclosure enable the PA 100 to concurrently achieve a linearity target and a power efficiency target across the full amplitude range of the RF output signal. This is in contrast to known approaches, according to which achieving a linearity target may adversely affect power efficiency, and/or achieving a power efficiency target may adversely affect linearity.

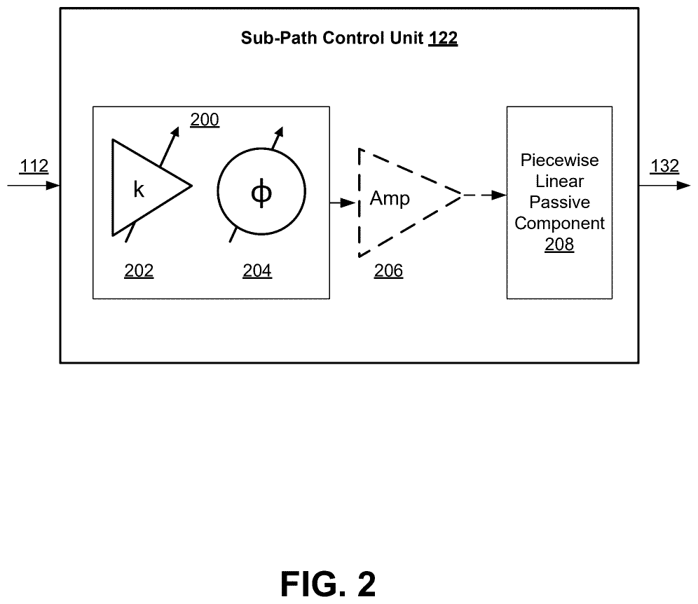

The PA 100 may concurrently achieve a linearity target and a power efficiency target based on the configurable sub-paths and the associated plurality of sub-path control units. A configurable sub-path may compensate for non-linearity in the sub-path itself, or in another sub-path. For example, based on a determined non-linearity in one or more other sub-paths, a configurable sub-path may provide one or more of phase control, gain control and bias control on its sub-path input signal to produce a related sub-path output signal that, when combined with the other sub-path output signals, enable the PA 100 to concurrently achieve a linearity target and a power efficiency target across the full amplitude range of the RF output signal. The example of compensating for a sub-path's own non-linearity will be described in further detail in relation to FIG. 2.

According to embodiments of the present disclosure, the RF output signal 104 concurrently achieves a linearity target and a power efficiency target across the full amplitude range of the RF output signal, even when at least one of the sub-path output signals has a piecewise linear response. The path output signals 152 and 154 combine so that the RF output signal 104 achieves the linearity target. In an example embodiment, one or more of the path output signals 152 and 154 may have a piecewise linear response, and for example each one can be piecewise linear. Similarly, the sub-path output signals 132, 134 and 136 combine so that the RF output signal 104 achieves the linearity target. In an example embodiment, one or more of the sub-path output signals 132, 134 and 136 may have a piecewise linear response, and for example each one can be piecewise linear. In such embodiments, one or more of the plurality of sub-path control units may be configured to compensate for the piecewise linear response of the path(s)/sub-path(s), so that the RF output signal achieves the linearity target.

In an example embodiment, the plurality of sub-path control units 122, 124 and 126 may be configured to cooperate so that a piecewise linear combination of the plurality of sub-path output signals 132, 134 and 136 by the combiner cooperates to concurrently achieve linearity and power efficiency across a full amplitude range of the RF output signal 104. For example, the combiner may include first and second path combiners 142 and 144 and PA combiner 160. In an example embodiment, the piecewise linear combination of the plurality of sub-path output signals may be configured to concurrently achieve linearity and power efficiency, for example using joint optimization or multi-variable optimization.

In an example implementation, the first sub-path signal may be associated with a driver sub-path of the first path, and the second sub-path signal may be associated with a secondary sub-path of the first path. In one embodiment, the secondary sub-path may be configured to achieve linearity optimization with respect to the driver sub-path. In another embodiment, the secondary sub-path may be configured to achieve gain optimization with respect to the driver sub-path. In a further embodiment, the secondary sub-path may be configured to achieve output power optimization with respect to the driver sub-path. In another embodiment, the secondary sub-path may be configured to achieve efficiency optimization with respect to the driver sub-path.

In a further embodiment, the secondary sub-path may be configured to simultaneously achieve linearity optimization and efficiency optimization with respect to the driver sub-path. In another embodiment, the secondary sub-path may be configured to simultaneously achieve linearity optimization, gain optimization, output power optimization and efficiency optimization with respect to the driver sub-path. In a yet further embodiment, the secondary sub-path may be configured to achieve linearity and power efficiency optimization with respect to the third sub-path.

Embodiments of the present disclosure provide improved performance over known approaches, such as a Doherty amplifier, for example by providing fine gain and phase control for each of a plurality of sub-paths. This permits embodiments of the disclosure to operate with at least one sub-path being piecewise linear, and still achieve a linearity target at the RF output, which would not be achievable with known approaches. Embodiments of the present disclosure may be beneficial when sub-paths have non-linear or piecewise linear response due to non-ideal characteristics compared to expected performance, which may be due to imperfections, degradation or other factors. Embodiments of the present disclosure may be applied to RF & mmWave communications and sensing.

Embodiments of the present disclosure provide sub-path control units that compensate for piecewise-linear (kink) sub-paths to achieve RF output linearization. A given driver path may have a multiplicity of sub-paths feeding it, enabling linearization across the full signal amplitude range. The kinks may be active and/or passive.

Embodiments of the present disclosure provide advanced control features, including fine phase & gain control of paths for optimization of gain, output power, linearity, and efficiency. Embodiments of the present disclosure also provide advanced diagnostics, such as voltage, current, and power measurement capabilities at various key points.

FIG. 2 illustrates a sub-path control unit for a sub-path of the power amplifier of FIG. 1, in accordance with one or more embodiments. The example embodiment in FIG. 2 shows the sub-path control unit 122, which is associated with sub-path 1.1 and with path 1, and configured to receive sub-path input signal 112 and to provide one or more of phase control, gain control and bias control to produce sub-path output signal 132. The sub-path control unit may comprise a combined phase and gain controller 200 configured to control phase and gain of the sub-path signal 112 to produce the sub-path output signal 132. In an example embodiment, the sub-path control unit may comprise a gain controller 202 and a phase controller 204. In an example implementation, the sub-path signal 112 may come in with 100 mV at 30 degrees, then the sub-path control unit with a combined phase and gain controller may be configured to amplify the signal to 200 mV but shift phase to 45 degrees. The sub-path control unit may be configured to control the bias voltage, for example using an amplifier 206.

In an embodiment, the sub-path control unit provides the ability for a sub-path to achieve a linearity target or have a piecewise linear shape by itself, without requiring combination with another sub-path. The sub-path control unit may comprise a piecewise linear passive component 208 configured to produce a piecewise-linear response for the configurable sub-path with which the sub-path control unit is associated. In such an embodiment, creating a piecewise linear response at the sub-path output results in a piecewise linear response at the path output.

In an embodiment, at least one of the plurality of sub-path control units comprises a combined phase and gain controller configured to control phase and gain of a selected sub-path signal and to produce a corresponding sub-path output signal.

In an embodiment, at least one of the plurality of sub-path control units comprises a bias voltage controller configured to control the bias voltage a selected sub-path signal and to produce a corresponding sub-path output signal.

In an embodiment, at least one of the plurality of sub-path control units comprises: a gain controller; and a phase controller, the phase controller being in communication with the gain controller to provide a gain and phase controlled output. In an embodiment, the at least one of the plurality of sub-path control units comprises an amplifier to increase the gain of the gain and phase-controlled output.

In one or more embodiments, the elements in FIG. 2 may be passive or active. In an example embodiment, the phase shifter may be passive. In an example embodiment, the gain adjustment may be passive.

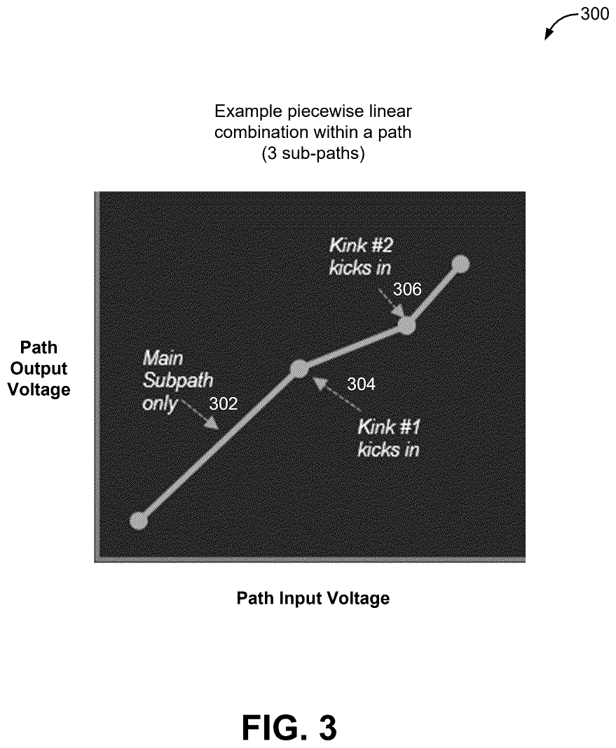

FIG. 3 illustrates a graph 300 showing path output voltage versus path input voltage for a piecewise linear combination within a path in a power amplifier, in accordance with one or more embodiments. As evidenced by the graph in FIG. 3, the main sub-path control unit and the one or more secondary sub-path control units cooperate such that the performance characteristics of the plurality of sub-paths provide a piecewise linear combination within a path. This results in a desired performance of path input/output voltage over an entire spectrum of an input signal and output signal. For example the piecewise linear combination may comprise a combination of the path output voltage versus path input voltage behaviour of the main sub-path 302, which may be a first sub-path or a driver path. Following that, the main sub-path 302 behaviour is combined at 304 with the behaviour of the first kink path or secondary path, then at 306 with the behaviour of the second kind path or secondary path.

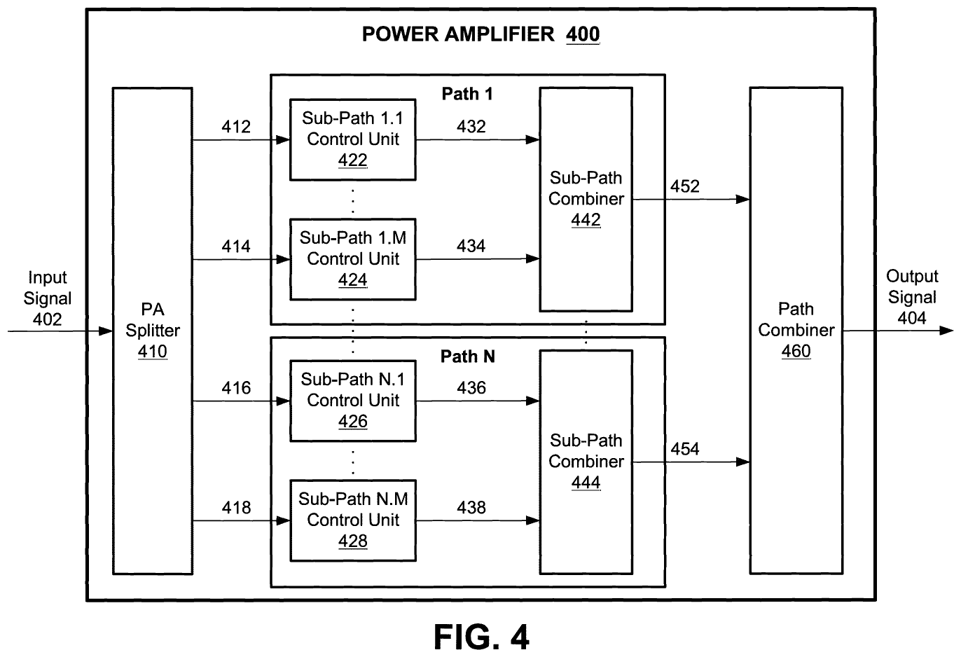

FIG. 4 is a block diagram illustrating a power amplifier 400 with N paths, in accordance with one or more embodiments. The RF PA 400 may receive and control an RF input signal 402, and may distribute or split the input signal 402 over different sub-paths.

The RF power amplifier 400 comprises a splitter 410 configured to perform a distribution, for example a linear separation, of the input signal 402 into a plurality of sub-path signals 412, 414, 416 and 418 distributed over a plurality of paths. This number of the plurality of sub-path signals is exemplary, and there may be any number of sub-path signals. The example of FIG. 4 shows an implementation in which up to N paths may be provided, with each of the N paths comprising up to M sub-paths.

In an example embodiment described in relation to FIG. 4, the plurality of sub-path signals includes first and second sub-path signals 412 and 414 associated with a first path, and third and fourth sub-path signals 416 and 418 associated with an Nth path. There may be any number of additional paths between the first path and the Nth path. First sub-path signal 412 may be described as relating to sub-path 1.1, and second sub-path signal 414 may be described as relating to sub-path 1.M, where sub-paths 1.1 through 1.M comprise up to M sub-paths of path 1. Similarly, third and fourth sub-path signals 416 and 418 may be described as relating to sub-path N.1 through N.M, which comprise up to M sub-paths of path N. There may be any number of additional sub-paths and associated sub-path signals between the first sub-path and the Mth sub-path for one or more of path 1 through path N.

The PA 400 comprises a plurality of sub-path control units 422, 424, 426 . . . 428 configured to receive the plurality of sub-path signals and to provide one or more of phase control, gain control and bias control of the plurality of sub-path signals distributed over a plurality of configurable sub-paths. For example, a configurable sub-path is a sub-path on which a sub-path control unit is provided. In an example embodiment, each of the plurality of paths comprises at least one configurable sub-path, and at least one of the plurality of paths comprises at least two configurable sub-paths. This is in contrast to some known approaches according to which each path can only have one sub-path. The plurality of sub-path control units are configured to produce a plurality of sub-path output signals.

For example, as part of path 1, sub-path 1.1 control unit 422 is associated with sub-path 1.1 and configured to receive sub-path input signal 412 and to provide one or more of phase control, gain control and bias control to produce sub-path output signal 432. Also as part of path 1, sub-path 1.M control unit 424 is associated with sub-path 1.M and configured to receive sub-path input signal 414 and to provide one or more of phase control, gain control and bias control to produce sub-path output signal 434. As part of path N, sub-path 2.1 control unit 426 is associated with sub-path 2.1 and configured to receive sub-path input signal 416 and to provide one or more of phase control, gain control and bias control to produce sub-path output signal 436. Also as part of path N, sub-path N.M control unit 428 is associated with sub-path N.M and configured to receive sub-path input signal 418 and to provide one or more of phase control, gain control and bias control to produce sub-path output signal 438.

There may be any number of additional paths between the first path and the Nth path. There may be any number of additional sub-paths and associated sub-path signals between the first sub-path and the Mth sub-path for one or more of path 1 through path N. In an example embodiment, the plurality sub-path control units is equal in number to the plurality of sub-path input signals, each of the plurality of sub-path control units being configured to receive a different one of the plurality of sub-path input signals and to provide one or more of phase control, gain control and bias control of the respective received sub-path signal, the plurality of sub-path control units producing the plurality of sub-path output signals.

The PA 400 may comprise a plurality of paths, and each path may have a plurality of sub-paths. In an example embodiment, each sub-path may comprise a sub-path control unit. In another example embodiment, a set of sub-path control units is provided on a subset of the sub-paths, and the set of sub-path control units may be configured to compensate for the piecewise linear response of one of more sub-path output signals. The piecewise linear response may be on a sub-path that has a sub-path control unit. Alternatively, the sub-path control unit(s) may compensate for a piecewise linear response on at least one sub-path having a piecewise linear response, even if the piecewise linear response is on a different sub-path than the sub-path control unit(s).

The PA 400 may comprise a combiner network configured to combine the plurality of sub-path output signals to generate an RF output signal. In the example embodiment of FIG. 4, a path combiner 460 combines signals provided from a plurality of sub-path combiners, for example sub-path combiner 442 through to sub-path combiner 444. First sub-path combiner 442 is configured to combine sub-path output signals 432 and 434 to generate a path 1 output signal 452. Nth path combiner 144 is configured to combine sub-path output signals for path N, which in this case includes 436 and 438, to generate a path N output signal 454. The path combiner 460 is configured to combine the sub-path output signals 452 and 454 to generate an RF output signal 404. There may be any number of additional paths between the first path and the Nth path, which may result in an equal number of associated path combiners. There may be any number of additional sub-paths and associated sub-path signals between the first sub-path and the Mth sub-path for one or more of path 1 through path N.

The plurality of configurable sub-paths may be configured, and the associated plurality of sub-path control units 422, 424 . . . 426 cooperate, such that the RF output concurrently achieves a linearity target and a power efficiency target across a full amplitude range of the RF output signal. The linearity target may comprise a target with respect to an amount of linearity for the RF output signal 404. The power efficiency target may comprise a target with respect to a power efficiency value or rating for the RF output signal 404. Embodiments of the present disclosure enable the PA 100 to concurrently achieve a linearity target and a power efficiency target across the full amplitude range of the RF output signal. This is in contrast to known approaches, according to which achieving a linearity target may adversely affect power efficiency, and/or achieving a power efficiency target may adversely affect linearity.

The PA 400 may concurrently achieve a linearity target and a power efficiency target based on the configurable sub-paths and the associated plurality of sub-path control units. A configurable sub-path may compensate for non-linearity in the sub-path itself, or in another sub-path. For example, based on a determined non-linearity in one or more other sub-paths, a configurable sub-path may provide one or more of phase control, gain control and bias control on its sub-path input signal to produce a related sub-path output signal that, when combined with the other sub-path output signals, enable the PA 400 to concurrently achieve a linearity target and a power efficiency target across the full amplitude range of the RF output signal.

In an example embodiment, the plurality of sub-path control units 422, 424, 426 . . . 428 may be configured to cooperate so that a piecewise linear combination of the plurality of sub-path output signals 432, 434, 436 . . . 438 by the combiner cooperates to concurrently achieve linearity and power efficiency across a full amplitude range of the RF output signal 404. For example, the combiner may include a plurality of path combiners 442 . . . 444 and PA combiner 460. In an example embodiment, the piecewise linear combination of the plurality of sub-path output signals may be configured to concurrently achieve linearity and power efficiency using joint optimization or multi-variable optimization.

According to embodiments of the present disclosure, the RF output signal 404 concurrently achieves a linearity target and a power efficiency target across the full amplitude range of the RF output signal, even when at least one of the sub-path output signals has a piecewise linear response. The path output signals 452 . . . 454 combine so that the RF output signal 404 achieves the linearity target. In an example embodiment, one or more of the path output signals 452 and 454 may have a piecewise linear response, and for example each one can be piecewise linear. Similarly, the sub-path output signals 432, 434, 436 and 438 combine so that the RF output signal 404 achieves the linearity target.

In an example embodiment, one or more of the sub-path output signals 432, 434, 436 and 438 may have a piecewise linear response, and for example each one can be piecewise linear. In such embodiments, one or more of the plurality of sub-path control units may be configured to compensate for the piecewise linear response of the path(s)/sub-path(s), so that the RF output signal achieves the linearity target. There may be any number of additional paths and associated path output signals between the first and Nth paths, any one or more of which can be piecewise linear. There may be any number of additional sub-paths and associated sub-path output signals between the first sub-path and the Mth sub-path for one or more of path 1 through path N, any one or more of which can be piecewise linear.

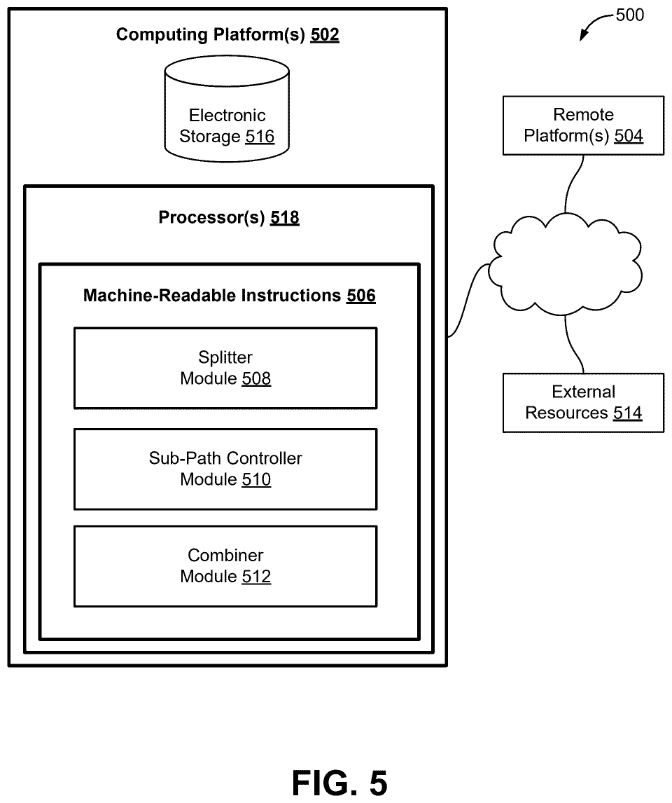

FIG. 5 is a functional block diagram illustrating an apparatus 500, in accordance with one or more embodiments, such as a load balanced power amplifier. The embodiments of FIG. 1 and FIG. 4 illustrate a system or PA in a specific implementations, which may be implemented in a product and at one location, for example with all of the elements being on-chip. The embodiment of FIG. 5 illustrates that some functionality may be distributed, or provided as modules.

In some embodiments, system 500 may include one or more computing platforms 502. Computing platform(s) 502 may be configured to communicate with one or more remote platforms 504 according to a client/server architecture, a peer-to-peer architecture, and/or other architectures. Remote platform(s) 504 may be configured to communicate with other remote platforms via computing platform(s) 502 and/or according to a client/server architecture, a peer-to-peer architecture, and/or other architectures. Users may access system 500 via remote platform(s) 504.

Computing platform(s) 502 may be configured by machine-readable instructions 506. Machine-readable instructions 506 may include one or more instruction modules. The instruction modules may include computer program modules. The instruction modules may include one or more of splitter module 508, sub-path controller module 510, combiner module 512, and/or other instruction modules.

Splitter module 508 may be configured to receive the RF input signal and to perform a distribution, such as a linear separation, of the RF input signal into a plurality of sub-path signals distributed over a plurality of paths.

Sub-path controller module 510 may be configured to perform one or more of phase control, gain control and bias control with respect to the plurality of sub-path signals to produce a plurality of sub-path output signals distributed over a plurality of configurable sub-paths. Each of the plurality of paths may comprise at least one configurable sub-path. At least one of the sub-path output signals has a piecewise linear response. In an example embodiment, at least one of the plurality of paths comprises at least two configurable sub-paths. In a particular example, the sub-path controller module 510 may comprise first, second and third sub-path control modules configured to receive the first, second and third sub-path signals, respectively, and to provide phase and gain control of the respective sub-path signal and produce first, second and third sub-path output signals.

Combiner module 512 may be configured to combine the plurality of sub-path output signals to generate an RF output signal. The plurality of configurable sub-paths may be configured, and the plurality of sub-path control units may cooperate, such that the RF output concurrently achieves a linearity target and a power efficiency target across a full amplitude range of the RF output signal. In an example implementation, a piecewise linear combination of the plurality of sub-path output signals cooperates to achieve linearity across a full amplitude range of the RF output signal. In an embodiment, the combiner module 512 may be configured to combine the first, second and third sub-path output signals to generate an RF output signal such that a piecewise linear combination of the first, second and third sub-path output signals by the combiner cooperates to concurrently achieve linearity and power efficiency across a full amplitude range of the RF output signal.

In one or more embodiments, one or more of the features and characteristics described above in relation to the PA splitter 110 of FIG. 1 or PAT splitter 410 of FIG. 4 may also be applied to the splitter module 508. In one or more embodiments, one or more of the features and characteristics described above in relation to the sub-path control units 122, 124, 126 of FIG. 1 or the sub-path control units 422, 424, 426 . . . 428 of FIG. 4 may also be applied to the sub-path controller module 510. In one or more embodiments, one or more of the features and characteristics described above in relation to the path combiner 160 of FIG. 1 or the path combiner 460 of FIG. 4 may also be applied to the combiner module 512.

In some embodiments, computing platform(s) 502, remote platform(s) 504, and/or external resources 514 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 502, remote platform(s) 504, and/or external resources 514 may be operatively linked via some other communication media.

A given remote platform 504 may include one or more processors configured to execute computer program modules. The computer program modules may be configured to enable an expert or user associated with the given remote platform 504 to interface with system 500 and/or external resources 514, and/or provide other functionality attributed herein to remote platform(s) 504. By way of non-limiting example, a given remote platform 504 and/or a given computing platform 502 may include one or more of a server, a desktop computer, a laptop computer, a handheld computer, a tablet computing platform, a NetBook, a Smartphone, a gaming console, and/or other computing platforms.

External resources 514 may include sources of information outside of system 500, external entities participating with system 500, and/or other resources. In some embodiments, some or all of the functionality attributed herein to external resources 514 may be provided by resources included in system 500.

Computing platform(s) 502 may include electronic storage 516, one or more processors 518, and/or other components. Computing platform(s) 502 may include communication lines, or ports to enable the exchange of information with a network and/or other computing platforms. Illustration of computing platform(s) 502 in FIG. 5 is not intended to be limiting. Computing platform(s) 502 may include a plurality of hardware, software, and/or firmware components operating together to provide the functionality attributed herein to computing platform(s) 502. For example, computing platform(s) 502 may be implemented by a cloud of computing platforms operating together as computing platform(s) 502.

Electronic storage 516 may comprise non-transitory storage media that electronically stores information. The electronic storage media of electronic storage 516 may include one or both of system storage that is provided integrally (i.e., substantially non-removable) with computing platform(s) 502 and/or removable storage that is removably connectable to computing platform(s) 502 via, for example, a port (e.g., a USB port, a firewire port, etc.) or a drive (e.g., a disk drive, etc.). Electronic storage 516 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 516 may include one or more virtual storage resources (e.g., cloud storage, a virtual private network, and/or other virtual storage resources). Electronic storage 516 may store software algorithms, information determined by processor(s) 518, information received from computing platform(s) 502, information received from remote platform(s) 504, and/or other information that enables computing platform(s) 502 to function as described herein.

Processor(s) 518 may be configured to provide information processing capabilities in computing platform(s) 502. As such, processor(s) 518 may include one or more of a digital processor, an analog processor, a digital circuit designed to process information, an analog circuit designed to process information, a state machine, and/or other mechanisms for electronically processing information. Although processor(s) 518 is shown in FIG. 5 as a single entity, this is for illustrative purposes only. In some embodiments, processor(s) 518 may include a plurality of processing units. These processing units may be physically located within the same device, or processor(s) 518 may represent processing functionality of a plurality of devices operating in coordination. Processor(s) 518 may be configured to execute modules 508, 510, and/or 512, and/or other modules. Processor(s) 518 may be configured to execute modules 508, 510, and/or 512, and/or other modules by software; hardware; firmware; some combination of software, hardware, and/or firmware; and/or other mechanisms for configuring processing capabilities on processor(s) 518. As used herein, the term “module” may refer to any component or set of components that perform the functionality attributed to the module. This may include one or more physical processors during execution of processor readable instructions, the processor readable instructions, circuitry, hardware, storage media, or any other components.

It should be appreciated that although modules 508, 510, and/or 512 are illustrated in FIG. 5 as being implemented within a single processing unit, in embodiments in which processor(s) 518 includes multiple processing units, one or more of modules 508, 510, and/or 512 may be implemented remotely from the other modules. The description of the functionality provided by the different modules 508, 510, and/or 512 described below is for illustrative purposes, and is not intended to be limiting, as any of modules 508, 510, and/or 512 may provide more or less functionality than is described. For example, one or more of modules 508, 510, and/or 512 may be eliminated, and some or all of its functionality may be provided by other ones of modules 508, 510, and/or 512. As another example, processor(s) 518 may be configured to execute one or more additional modules that may perform some or all of the functionality attributed below to one of modules 508, 510 and/or 512.

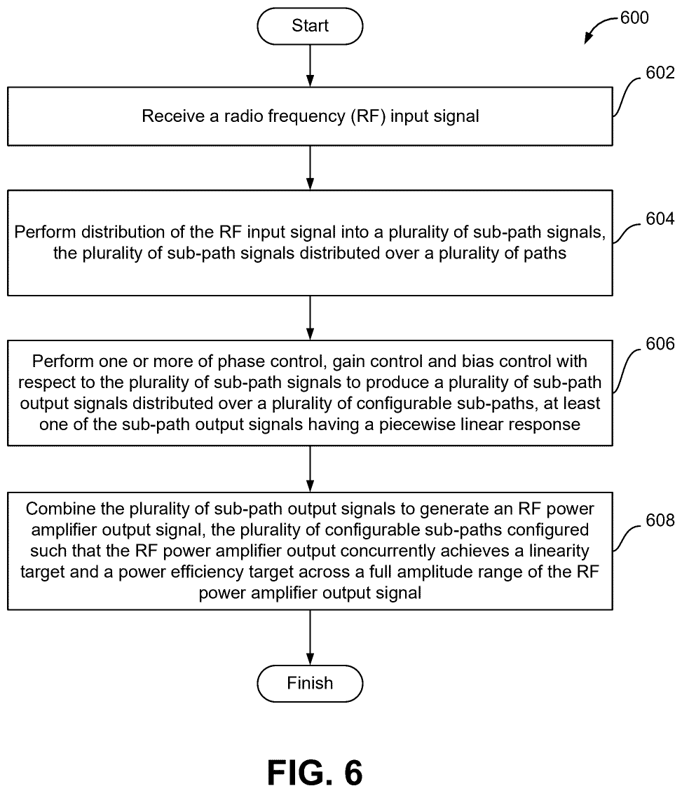

FIG. 6 illustrates a method 600 for processing a signal in a power amplifier, in accordance with one or more embodiments. The operations of method 600 presented below are intended to be illustrative. In some embodiments, method 600 may be accomplished with one or more additional operations not described, and/or without one or more of the operations discussed. Additionally, the order in which the operations of method 600 are illustrated in FIG. 6 and described below is not intended to be limiting.

In some embodiments, method 600 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 600 in response to instructions stored electronically on an electronic storage medium. The one or more processing devices may include one or more devices configured through hardware, firmware, and/or software to be specifically designed for execution of one or more of the operations of method 600.

An operation 602 may include receiving a radio frequency (RF) input signal. Operation 602 may be performed by a PA splitter, such as PA splitter 110 in FIG. 1 or PA splitter 410 in FIG. 4, or by one or more hardware processors configured by machine-readable instructions including a module that is the same as or similar to splitter module 508 in FIG. 5, in accordance with one or more embodiments.

An operation 604 may include performing a distribution, such as a linear separation, of the RF input signal into a plurality of sub-path signals distributed over a plurality of paths. Each of the plurality of paths comprises at least one configurable sub-path. At least one of the sub-path output signals has a piecewise linear response. The plurality of sub-path signals may include first and second sub-path signals associated with a first path and a third sub-path signal associated with a second path. Operation 604 may be performed by a PA splitter, such as PA splitter 110 in FIG. 1 or PA splitter 410 in FIG. 4, or by one or more hardware processors configured by machine-readable instructions including a module that is the same as or similar to splitter module 508 in FIG. 5, in accordance with one or more embodiments.

An operation 606 may include performing one or more of phase control, gain control and bias control with respect to the plurality of sub-path signals to produce a plurality of sub-path output signals. For example, operation 606 may comprise receiving first, second and third sub-path signals and providing phase and gain control to produce first, second and third sub-path output signals. In another example, operation 606 may comprise providing one or more of phase control, gain control or bias control. Operation 606 may be performed by one or more of sub-path control units 122, 124, 126 of FIG. 1 or one or more of sub-path control units 422, 424, 426 . . . 428 of FIG. 4, or by one or more hardware processors configured by machine-readable instructions including a module that is the same as or similar to sub-path controller module 510, in accordance with one or more embodiments.

An operation 608 may include combining the plurality of sub-path output signals to generate an RF output signal. The plurality of configurable sub-paths may be configured, and the plurality of sub-path control units may cooperate, such that the RF output concurrently achieves a linearity target and a power efficiency target across a full amplitude range of the RF output signal. In an example implementation, a piecewise linear combination of the plurality of sub-path output signals cooperates to achieve linearity across a full amplitude range of the RF output signal. Operation 608 may include combining the first, second and third sub-path output signals to generate an RF output signal such that a piecewise linear combination of the first, second and third sub-path output signals by the combiner cooperates to concurrently achieve linearity and power efficiency across a full amplitude range of the RF output signal. Operation 608 may be performed by the path combiner 160 of FIG. 1 or the path combiner 460 of FIG. 4. Operation 608 may be performed by one or more hardware processors configured by machine-readable instructions including a module that is the same as or similar to combiner module 512, in accordance with one or more embodiments.

Embodiments of the present disclosure provide a load-modulated intelligent RF power amplifier comprising at least two and up to N driver paths, with at least one path, each path comprising up to M sub-paths. Each set of M sub-paths may comprise a main sub-path, and zero or more secondary sub-paths. A separate phase and gain control unit may be provided for each sub-path, providing fine phase and gain control of the sub-paths, for optimization of gain, output power, linearity and efficiency. Embodiments of the present disclosure are able to account for changes in environment and for manufacturing variances, resulting in desirable performance characteristics for the power amplifier, which are less affected by or unaffected by environmental and manufacturing variations.

Embodiments of the present disclosure are designed to operate in scenarios in which at least one sub-path in the PA has a non-linear response, such as a piecewise linear response. A piecewise linear response is a combination of straight lines that is not linear as a whole; each section or piece may be linear, but the overall curve is not linear. When at least one-sub path in the PA has a non-linear response, then at least one path has a non-linear response. The sub-path control units of embodiments of the present disclosure are configured to compensate for non-linearity in one or more of the sub-paths to achieve the linearity target for the RF output signal.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a compact disk read only memory (CD-ROM), digital versatile disk (DVD), Blu-ray Disc Read Only Memory (BD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

Embodiments of the disclosure can be described with reference to the following clauses, with specific features laid out in the dependent clauses.

In an embodiment, the present disclosure provides a radio frequency power amplifier comprising: a splitter configured to perform a distribution of an RF input signal into a plurality of sub-path input signals distributed over a plurality of paths; a plurality of sub-path control units configured to receive the plurality of sub-path input signals and to provide one or more of phase control, gain control and bias control to produce a plurality of sub-path output signals distributed over a plurality of configurable sub-paths, each of the plurality of paths comprising at least one configurable sub-path, at least one of the sub-path output signals having a piecewise linear response; a plurality of sub-path combiners configured to combine the plurality of sub-path output signals into a plurality of path signals; and a path combiner configured to combine the plurality of path signals and to generate an RF output signal, the plurality of configurable sub-paths being configured, and the plurality of sub-path control units cooperating, such that the RF output concurrently achieves a linearity target and a power efficiency target across a full amplitude range of the RF output signal.

In an example embodiment, the path combiner is configured to combine the plurality of path signals and to facilitate load modulation to achieve the power efficiency target.

In an example embodiment, at least one of the plurality of sub-path control units comprises an RF signal amplifier contributing to the one or more of phase control, gain control and bias control and to achieving the linearity target.

In an example embodiment, each of the plurality of sub-path control units comprises an RF signal amplifier contributing to the one or more of phase control, gain control and bias control and to achieving the linearity target, the plurality of sub-paths being configured to use different biasing values for the RF signal amplifier in each configurable sub-path.

In an example embodiment, at least one of the plurality of sub-path control units comprises a piecewise-linear passive component configured to produce a piecewise-linear response for the configurable sub-path associated with the at least one of the plurality of sub-path control units.

In an example embodiment, the plurality of configurable sub-paths are configured and the plurality of sub-path control units cooperate to produce a piecewise-linear response for one or more of the plurality of configurable sub-paths.

In an example embodiment, the plurality of configurable sub-paths are configured and the plurality of sub-path control units cooperate to produce a piecewise-linear response for one or more of the plurality of paths.

In an example embodiment, at least one of the plurality of sub-path control units is configured and the plurality of sub-path control units cooperate to produce a piecewise-linear response for one or more of the plurality of sub-paths.

In an example embodiment, the plurality of sub-path control units is configured to provide two or more of phase control, gain control and bias control to produce the plurality of sub-path output signals.

In an example embodiment, the plurality of sub-path control units is configured to provide phase control, gain control and bias control to produce the plurality of sub-path output signals.

In an example embodiment, at least one of the plurality of paths comprises at least two sub-paths.

In an example embodiment, the plurality of configurable sub-paths are configured, and the plurality of sub-path control units cooperate, to achieve an efficiency target with respect to one or more of the configurable sub-paths, the paths or the RF output signal.

In an example embodiment, the plurality of configurable sub-paths are configured, and the plurality of sub-path control units cooperate, to simultaneously achieve an efficiency target and the linearity target with respect to one or more of the configurable sub-paths, the paths or the RF output signal.

In an example embodiment, the plurality of configurable sub-paths are configured, and the plurality of sub-path control units cooperate, to simultaneously achieve the linearity target, the power efficiency target and a gain target with respect to one or more of the configurable sub-paths, the paths or the RF output signal.

In an example embodiment, at least one of the plurality of sub-path control units comprises a combined phase and gain controller configured to control phase and gain of a selected sub-path signal and to produce a corresponding sub-path output signal.

In an example embodiment, at least one of the plurality of sub-path control units comprises a bias voltage controller configured to control the bias voltage of a selected sub-path signal and to produce a corresponding sub-path output signal.

In an example embodiment, at least one of the plurality of sub-path control units comprises: a gain controller; and a phase controller; the phase controller being in communication with the gain controller to provide a gain and phase controlled output.

In an example embodiment, the plurality sub-path control units is equal in number to the plurality of sub-path input signals, each of the plurality of sub-path control units being configured to receive a different one of the plurality of sub-path input signals and to provide one or more of phase control, gain control and bias control of the respective received sub-path signal, the plurality of sub-path control units producing the plurality of sub-path output signals.

In an embodiment, the present disclosure provides a processor-implemented method for processing a radio frequency (RF) input signal, the method comprising: receiving the RF input signal; performing a distribution of the RF input signal into a plurality of sub-path signals, the plurality of sub-path signals distributed over a plurality of paths; performing one or more of phase control, gain control and bias control with respect to the plurality of sub-path signals to produce a plurality of sub-path output signals distributed over a plurality of configurable sub-paths, at least one of the sub-path output signals having a piecewise linear response; and combining the plurality of sub-path output signals to generate an RF output signal, the plurality of configurable sub-paths configured such that the RF output concurrently achieves a linearity target and a power efficiency target across a full amplitude range of the RF output signal.

In an embodiment, the present disclosure provides an apparatus comprising: a non-transient computer-readable storage medium having executable instructions embodied thereon; and one or more hardware processors configured to execute the instructions to: receive the RF input signal; perform a distribution of the RF input signal into a plurality of sub-path signals, the plurality of sub-path signals distributed over a plurality of paths; perform one or more of phase control, gain control and bias control with respect to the plurality of sub-path signals to produce a plurality of sub-path output signals distributed over a plurality of configurable sub-paths, at least one of the sub-path output signals having a piecewise linear response; and combine the plurality of sub-path output signals to generate an RF output signal, the plurality of configurable sub-paths configured such that the RF output concurrently achieves a linearity target and a power efficiency target across a full amplitude range of the RF output signal.

In an embodiment, the present disclosure provides a radio frequency power amplifier comprising: a splitter configured to perform a distribution of an RF input signal into a plurality of sub-path input signals distributed over a plurality of paths; a plurality of sub-path control units, each of the plurality of sub-path control units configured to receive a selected one of the plurality of sub-path input signals and to provide one or more of phase control, gain control and bias control of the selected one of the plurality of sub-path signals, the plurality of sub-path control units producing a plurality of sub-path output signals distributed over a plurality of configurable sub-paths, at least one of the sub-path output signals having a piecewise linear response; and a combiner network configured to combine the plurality of sub-path output signals to generate an RF output signal, the plurality of configurable sub-paths being configured, and the plurality of sub-path control units cooperating, such that the RF output achieves a linearity target and/or a power efficiency target across a full amplitude range of the RF output signal.

In an embodiment, the present disclosure provides a radio frequency power amplifier comprising: a splitter configured to perform a distribution of an RF input signal into a plurality of sub-path input signals distributed over a plurality of paths; a plurality of sub-path control units configured to receive the plurality of sub-path input signals and to provide one or more of phase control, gain control and bias control to produce a plurality of sub-path output signals distributed over a plurality of configurable sub-paths, each of the plurality of paths comprising at least one configurable sub-path, at least one of the sub-path output signals having a non-linear response, a plurality of sub-path combiners configured to combine the plurality of sub-path output signals into a plurality of path signals; and a path combiner configured to combine the plurality of path signals and to generate an RF output signal, the plurality of configurable sub-paths being configured, and the plurality of sub-path control units cooperating, such that the RF output concurrently achieves a linearity target and a power efficiency target across a full amplitude range of the RF output signal.

In an embodiment, the present disclosure provides a processor-implemented method for processing a radio frequency (RF) input signal, the method comprising: receiving the RF input signal; performing a distribution of the RF input signal into a plurality of sub-path signals, the plurality of sub-path signals distributed over a plurality of paths; performing one or more of phase control, gain control and bias control with respect to the plurality of sub-path signals to produce a plurality of sub-path output signals distributed over a plurality of configurable sub-paths, at least one of the sub-path output signals having a non-linear response; and combining the plurality of sub-path output signals to generate an RF output signal, the plurality of configurable sub-paths configured such that the RF output concurrently achieves a linearity target and a power efficiency target across a full amplitude range of the RF output signal.

In an embodiment, the present disclosure provides an apparatus comprising: a non-transient computer-readable storage medium having executable instructions embodied thereon; and one or more hardware processors configured to execute the instructions to: receive the RF input signal; perform a distribution of the RF input signal into a plurality of sub-path signals, the plurality of sub-path signals distributed over a plurality of paths; perform one or more of phase control, gain control and bias control with respect to the plurality of sub-path signals to produce a plurality of sub-path output signals distributed over a plurality of configurable sub-paths, at least one of the sub-path output signals having a non-linear response; and combine the plurality of sub-path output signals to generate an RF output signal, the plurality of configurable sub-paths configured such that the RF output concurrently achieves a linearity target and a power efficiency target across a full amplitude range of the RF output signal.

1. A radio frequency (RF) power amplifier comprising:
a splitter configured to perform a distribution of an RF input signal into a plurality of sub-path input signals distributed over a plurality of paths;
a plurality of sub-path control units configured to receive the plurality of sub-path input signals and to provide one or more of phase control, gain control and bias control to produce a plurality of sub-path output signals distributed over a plurality of configurable sub-paths,
each of the plurality of paths comprising at least one configurable sub-path,
at least one of the sub-path output signals having a piecewise linear response,
a plurality of sub-path combiners configured to combine the plurality of sub-path output signals into a plurality of path signals; and
a path combiner configured to combine the plurality of path signals and to generate an RF output signal,
the plurality of configurable sub-paths being configured, and the plurality of sub-path control units cooperating, such that the RF output concurrently achieves a linearity target and a power efficiency target across a full amplitude range of the RF output signal.

2. The RF power amplifier of claim 1 wherein the path combiner is configured to combine the plurality of path signals and to facilitate load modulation to achieve the power efficiency target.

3. The RF power amplifier of claim 1 wherein:
at least one of the plurality of sub-path control units comprises an RF signal amplifier contributing to the one or more of phase control, gain control and bias control and to achieving the linearity target.

4. The RF power amplifier of claim 1 wherein:
each of the plurality of sub-path control units comprises an RF signal amplifier contributing to the one or more of phase control, gain control and bias control and to achieving the linearity target, the plurality of sub-paths being configured to use different biasing values for the RF signal amplifier in each configurable sub-path.

5. The RF power amplifier of claim 1 wherein:
at least one of the plurality of sub-path control units comprises a piecewise-linear passive component configured to produce a piecewise-linear response for the configurable sub-path associated with the at least one of the plurality of sub-path control units.

6. The RF power amplifier of claim 1 wherein:
the plurality of configurable sub-paths are configured and the plurality of sub-path control units cooperate to produce a piecewise-linear response for one or more of the plurality of configurable sub-paths.

7. The RF power amplifier of claim 1 wherein:
the plurality of configurable sub-paths are configured and the plurality of sub-path control units cooperate to produce a piecewise-linear response for one or more of the plurality of paths.

8. The RF power amplifier of claim 1 wherein:
at least one of the plurality of sub-path control units is configured and the plurality of sub-path control units cooperate to produce a piecewise-linear response for one or more of the plurality of sub-paths.

9. The RF power amplifier of claim 1 wherein:
the plurality of sub-path control units is configured to provide two or more of phase control, gain control and bias control to produce the plurality of sub-path output signals.

10. The RF power amplifier of claim 1 wherein:
the plurality of sub-path control units is configured to provide phase control, gain control and bias control to produce the plurality of sub-path output signals.

11. The RF power amplifier of claim 1 wherein at least one of the plurality of paths comprises at least two sub-paths.

12. The RF power amplifier of claim 1 wherein:
the plurality of configurable sub-paths are configured, and the plurality of sub-path control units cooperate, to achieve an efficiency target with respect to one or more of the configurable sub-paths, the paths or the RF output signal.

13. The RF power amplifier of claim 1 wherein:
the plurality of configurable sub-paths are configured, and the plurality of sub-path control units cooperate, to simultaneously achieve an efficiency target and the linearity target with respect to one or more of the configurable sub-paths, the paths or the RF output signal.

14. The RF power amplifier of claim 1 wherein:
the plurality of configurable sub-paths are configured, and the plurality of sub-path control units cooperate, to simultaneously achieve the linearity target, the power efficiency target and a gain target with respect to one or more of the configurable sub-paths, the paths or the RF output signal.

15. The RF power amplifier of claim 1 wherein:
at least one of the plurality of sub-path control units comprises a combined phase and gain controller configured to control phase and gain of a selected sub-path signal and to produce a corresponding sub-path output signal.

16. The RF power amplifier of claim 1 wherein:
at least one of the plurality of sub-path control units comprises a bias voltage controller configured to control the bias voltage of a selected sub-path signal and to produce a corresponding sub-path output signal.

17. The RF power amplifier of claim 1 wherein:
at least one of the plurality of sub-path control units comprises:
a gain controller; and
a phase controller;
the phase controller being in communication with the gain controller to provide a gain and phase controlled output.

18. The RF power amplifier of claim 1 wherein:
the plurality sub-path control units is equal in number to the plurality of sub-path input signals, each of the plurality of sub-path control units being configured to receive a different one of the plurality of sub-path input signals and to provide one or more of phase control, gain control and bias control of the respective received sub-path signal, the plurality of sub-path control units producing the plurality of sub-path output signals.

19. A processor-implemented method for processing a radio frequency (RF) input signal, the method comprising:
receiving the RF input signal;
performing a distribution of the RF input signal into a plurality of sub-path signals, the plurality of sub-path signals distributed over a plurality of paths;
performing one or more of phase control, gain control and bias control with respect to the plurality of sub-path signals to produce a plurality of sub-path output signals distributed over a plurality of configurable sub-paths, at least one of the sub-path output signals having a piecewise linear response; and
combining the plurality of sub-path output signals to generate an RF output signal, the plurality of configurable sub-paths configured such that the RF output concurrently achieves a linearity target and a power efficiency target across a full amplitude range of the RF output signal.

20. An apparatus comprising:
a non-transient computer-readable storage medium having executable instructions embodied thereon; and
one or more hardware processors configured to execute the instructions to:
receive the RF input signal;
perform a distribution of the RF input signal into a plurality of sub-path signals, the plurality of sub-path signals distributed over a plurality of paths;
perform one or more of phase control, gain control and bias control with respect to the plurality of sub-path signals to produce a plurality of sub-path output signals distributed over a plurality of configurable sub-paths, at least one of the sub-path output signals having a piecewise linear response; and
combine the plurality of sub-path output signals to generate an RF output signal, the plurality of configurable sub-paths configured such that the RF output concurrently achieves a linearity target and a power efficiency target across a full amplitude range of the RF output signal.
